(19) United States
(12) Patent Application Publication
(10) Pub. No.: US 2026/0143644 A1
(43) Pub. Date: May 21, 2026

(54) SERVER POWER SUPPLY UNIT EXHAUST DUCT

(71) Applicant: AMD Design, LLC, Wilmington, DE (US)

(72) Inventors: Ting Yu LIN, Fairfield, NJ (US); Haiyan LUO, Township, NJ (US)

(73) Assignee: AMD Design, LLC, Wilmington, DE (US)

(21) Appl. No.: 18/955,292

(22) Filed: Nov. 21, 2024

(51) Int. Cl. H05K 7/20; H05K 7/14

(52) U.S. Cl. CPC H05K 7/20727; H05K 7/1492; H05K 7/20909

(57) ABSTRACT

A power supply unit (PSU) exhaust duct includes a plurality of duct walls configured to, when attached to a server, form an enclosed space in communication with a PSU exhaust port of a PSU of the server and an interior space of the server that is outside of the PSU. The PSU exhaust port may be disposed at a rear wall of the server, and the PSU exhaust duct may be attached to a rear wall of the server. By connecting the PSU exhaust port to the interior space of the server, PSU fans of the PSU become in series with server fans of the server (e.g., main cooling fans of the server). Doing so may increase an amount of cool air flowing through the PSU compared to conventional means where the PSU fans and the server fans are in parallel.

### FIELD

This disclosure is directed to forced air flows around and through power supply units (PSUs) of servers.

### BACKGROUND

Servers include power supply units (PSUs) that are configured to provide power to components within the servers. Those components generate heat, and the servers include server fans that are, in conjunction with other features of the servers, configured to draw cooler air from outside the servers (e.g., from “cold” aisles of a data center having one or more rows or other groups of server racks), cause the air to flow across the components to gather heat from them, and exhaust the hotter air outside the servers (e.g., to “hot” aisles of the data center).

The PSUs also include components that generate heat, and the PSUs include PSU fans configured to draw cooler air from outside the PSUs (e.g., from colder areas within the servers), cause the air to flow across components within the PSUs to gather heat from the components, and exhaust the hotter air outside the servers (e.g., to the “hot” aisles of the data center). Thus, the PSU fans and the server fans are often configured to exhaust to a same space (e.g., the “hot aisles”).

### SUMMARY

A power supply unit (PSU) exhaust duct is described herein. The PSU exhaust duct includes a plurality of duct walls configured to, when attached to a server, form an enclosed space. The enclosed space is in communication with a PSU exhaust port of a PSU of the server and an interior space of the server that is outside of the PSU.

A first server is also described herein. The first server includes a PSU with a PSU exhaust port and one or more PSU fans configured to force air out of the PSU via the PSU exhaust port. The first server also includes a PSU exhaust duct forming an enclosed space in communication with the PSU exhaust port and an interior space of the first server that is outside of the PSU.

A second server is also described herein. This second server includes a server rear wall and a server exhaust port formed by the server rear wall. The second server exhaust port is in communication with an exterior of the second server. The second server also includes one or more server fans disposed proximate the second server exhaust port that are configured to receive air from an interior of the second server and force the air out of the second server via the second server exhaust port. The second server further includes a PSU including a PSU exhaust port and one or more PSU fans configured to force air out of the PSU via the PSU exhaust port and into the interior of the second server.

The foregoing summary is illustrative only and is not intended to be in any way limiting. In addition to the illustrative aspects, implementations, and features described above, further aspects, implementations, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a conventional implementation of a server with a PSU and airflow therethrough.

FIG. 2 illustrates an example of a portion of a server with a PSU and a PSU exhaust duct implemented therein.

FIG. 3 illustrates an example of the PSU exhaust duct of FIG. 2.

FIG. 4 illustrates airflow through the server of FIG. 2.

FIG. 5 illustrates an example of a server with an alternative implementation of a PSU.

FIG. 6 illustrates an example of a server with yet one more implementation of a PSU.

### DETAILED DESCRIPTION

### Overview

In most cases, power supply unit (PSU) fans are not as strong as server or chassis fans. Accordingly, when PSU fans and server fans exhaust to a similar space (e.g., are in parallel), air flow through the PSUs is often diminished, or even reversed, due to higher high-pressure areas and lower low-pressure areas caused by the server fans. If the air flow is reversed, hot exhaust gas from the server fans is often recirculated back through the PSUs and into the servers. The poor/reversed flow through the PSUs may cause the PSUs to overheat, batteries of the PSUs (if included) to overheat, increased temperatures in the servers, and increased power consumption of the PSU fans (e.g., in order to compensate for the lower or reversed flow).

Described herein is a PSU exhaust duct. The PSU exhaust duct includes a plurality of duct walls configured to, when attached to a server, form an enclosed space in communication with a PSU exhaust port of a PSU of the server and an interior space of the server that is outside of the PSU. For example, the PSU exhaust port may be disposed at a rear wall of the server, and the PSU exhaust duct may be attached to a rear wall of the server proximate the PSU.

By connecting the PSU exhaust port to the interior space of the server, PSU fans of the PSU effectively become in series with server fans of the server (e.g., main cooling fans of the server). Doing so increases an amount of cool air flowing through the PSU, which can lead to lower PSU temperatures, lower PSU battery temperatures, lower temperatures in the server, and decreased power consumption of the PSU fans.

In the following description, numerous specific details are set forth, such as particular structures, components, materials, dimensions, processing steps and techniques, in order to provide an understanding of the various implementations of the present application. However, it will be appreciated by one of ordinary skill in the art that the various implementations of the present application may be practiced without these specific details. In other instances, well-known structures or processing steps have not been described in detail in order to avoid obscuring the present application.

### Conventional Server

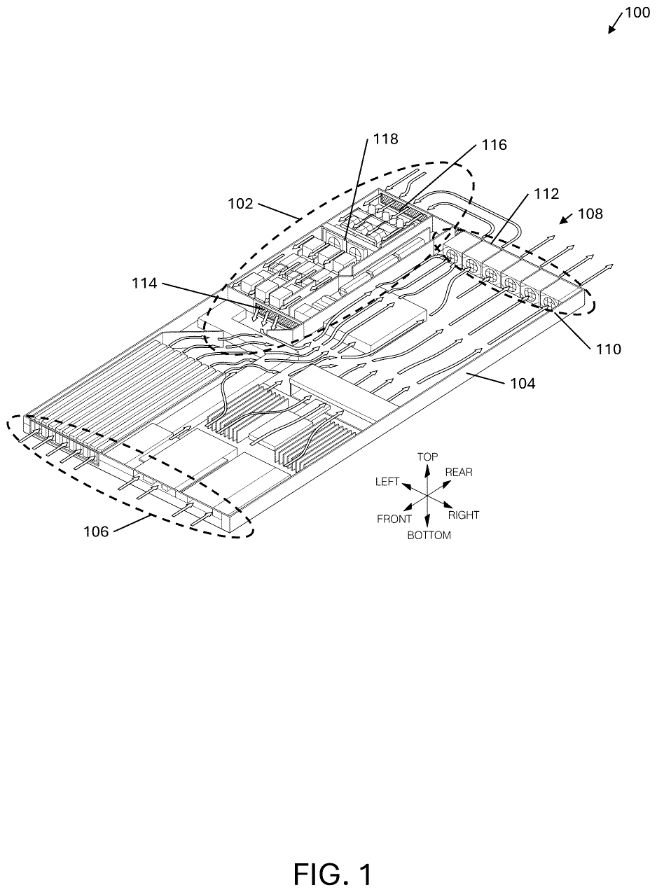

FIG. 1 illustrates an example of a conventional implementation of a server 100 with a PSU 102 and an example airflow therethrough. The server 100 includes a chassis 104 that includes at least one server intake port 106 and at least one server exhaust port 108 configured to let air pass therethrough. The server intake port 106 and/or the server exhaust port 108 may include any number of apertures, holes, slots, other voids, or some combination thereof formed by walls of the chassis 104. For example, the server intake port 106 and/or the server exhaust port 108 may be formed within one or more walls of the chassis 104 or be formed by a gap within one or more walls of the chassis 104 (e.g., an intermittent wall). The server intake port 106 is configured to be in contact with a cool air supply (e.g., a “cold” aisle of a data center having one or more rows or other groups of server racks), and the server exhaust port 108 is configured to be in contact with a hot air sink (e.g., a “hot” aisle of the data center). The server intake port 106 may span a width of the server 100 while the server exhaust port 108 may only span a portion of the width of the server 100.

The server 100 includes one or more server fans 110 that are configured to generate flow between the server intake port 106 and the server exhaust port 108. The server fans 110 may be disposed proximate the server exhaust port 108 (e.g., on or near a server rear wall 112) and configured to force air from an interior of the server 100 through the server exhaust port 108. A negative pressure within the interior of the server 100 generated by the server fans 110 causes air to be drawn in through the server intake port 106.

The PSU 102 includes a PSU intake port 114 and a PSU exhaust port 116 and one or more PSU fans 118 configured to move air therebetween. The PSU intake port 114 may be in communication with the interior of the server 100. The PSU exhaust port 116 may be in communication with an exterior of the server 100. The PSU exhaust port 116 may form a portion of a rear of the server 100 (e.g., if the PSU 102 is insertable from a rear of the server 100). As such, the chassis 104 may include a cutout or other structure configured to accommodate the PSU 102. Alternatively, the PSU exhaust port 116 may be in communication with the server exhaust port 108. In other words, the server exhaust port 108 (e.g., as a portion of the server rear wall 112) may extend across a width of the server 100, the server fans 110 may exhaust through a portion of the server exhaust port 108, and the PSU fans 118 may exhaust through another portion of the server exhaust port 108. Regardless of how the ports are implemented, the server fans 110 and the PSU fans 118 exhaust to a similar space (e.g., outside the rear of the server 100).

As discussed above, the PSU fans 118 attempt to flow air from the PSU intake port 114 to the PSU exhaust port 116. However, because the server fans 110 are generally more powerful than the PSU fans 118, the flow may be reversed though the PSU 102 due to stronger high-and low-pressure systems generated by the server fans 110 than the PSU fans 118. That is, the PSU exhaust port 116 effectively becomes an intake port, and the PSU intake port 114 effectively becomes an exhaust port. Accordingly, warm air exhausted by at least one of the server fans 110 (and other server fans when installed in a rack with multiple servers) flows through the PSU 102 instead of cooler air from the server intake port 106. This may lead to overheating of the PSU 102 and/or the server 100, excess current draw from the PSU fans 118, increased noise, or other issues.

In at least some implementations, PSU fans 118 and server fans 110 move different amounts of air. Such difference may be caused by a difference in fan size, fan power, fan configuration, fan speed, or other operating parameters of the fans, or for still other reasons. Among other things, FIG. 1 includes various arrows demonstrating at least one set of airflow patterns that may occur during operation of server 100. In FIG. 1, for example, rather than forcing air from inside the PSU 102 to the hot aisle through the PSU exhaust port 116, air may move from the hot aisle through the PSU exhaust port 116, into the PSU 102, out through the PSU intake port 114, and into the interior of the server 100. Accordingly, the airflow may be reversed from a desired airflow.

### Server With PSU Exhaust Duct

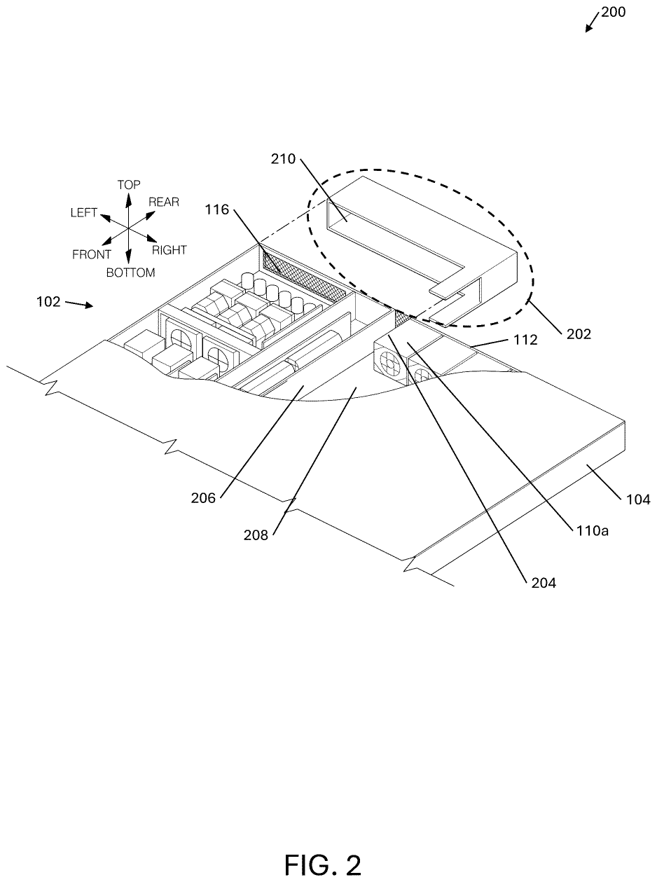

FIG. 2 illustrates an example of a server 200 with a PSU exhaust duct 202 implemented therein. The server 200 is illustrated with the PSU exhaust duct 202 pulled away from the rest of the server 200 to show various features. However, the PSU exhaust duct 202 is integral to and/or is configured to be integrated with the rest of the server 200. In some cases, for example, the PSU exhaust duct 202 is part of the PSU 102. In some cases, the PSU exhaust duct 202 is a separate and discrete component. Furthermore, the PSU exhaust duct 202 may be an integral part of a power distribution unit (PDU) (not shown) that the PSU 102 electrically couples to. Many of the components of the server 200 are similar to the server 100, thus, the same reference numbers will be used.

It should be noted that, in some implementations, a gap 204 exists between a side wall 206 of the PSU 102 that is closest to a centerline of the server 200 and one of the server fans 110 (e.g., server fan 110a) that is closest to the centerline of the server 200. The gap 204 enables communication between an interior 208 of the server 200 and an exterior of the server 200 proximate the server rear wall 112. That is, the gap 204 may communicate between the interior 208 and exterior of the server 200, or the server rear wall 112 may be configurable to allow the gap 204 to communicate between the interior 208 and exterior of the server 200 (e.g., by creating a port, hole, aperture, gap, pass-through, screen, grate, or the like in the server rear wall 112). The gap 204 may be pre-existing, or, in some implementations, the server fans 110 may be rearranged/reconfigured to create the gap between the server fans 110 and the PSU 102.

The PSU exhaust duct 202 is configured to route air from the PSU exhaust port 116 to the interior 208 via the gap 204. To do so, the PSU exhaust duct 202 is mounted proximate the PSU exhaust port 116. For example, the PSU exhaust duct 202 may be mounted to the PSU 102, the chassis 104 (e.g., the server rear wall 112), or some combination thereof. The PSU exhaust duct 202 may include one or more mounting portions (not shown) that are configured to attach the PSU exhaust duct 202 to the rest of the server 200. The PSU exhaust duct 202, when mounted, forms an enclosed space 210 in communication with the PSU exhaust port 116 and the interior 208. The enclosed space 210 may extend to, into, and/or through the gap 204. Doing so prevents hot exhaust from the server fans 110 from being forced or otherwise recirculated through the PSU 102 via the PSU exhaust port 116. Furthermore, an amount of cold air that is forced through the PSU 102 via the PSU intake port 114 may be increased.

### PSU Exhaust Duct

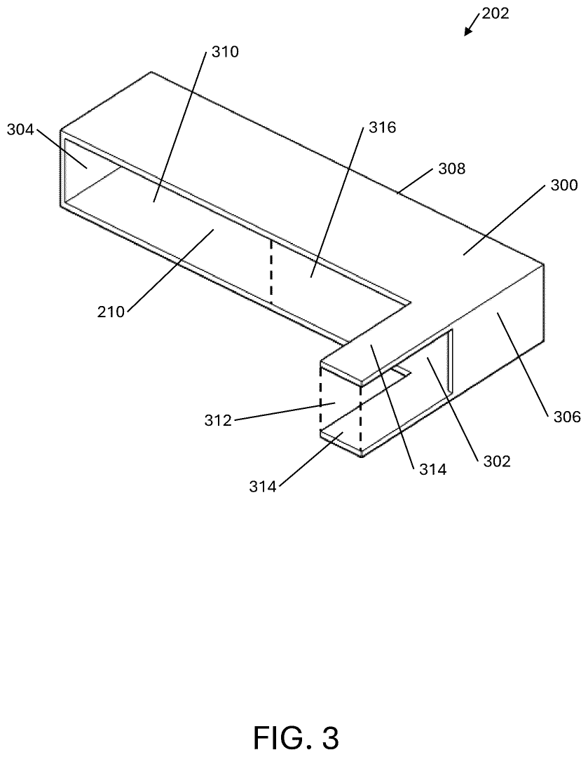

FIG. 3 illustrates an example of the PSU exhaust duct 202. The PSU exhaust duct 202 includes a top wall 300, a bottom wall 302, a left wall 304, a right wall 306, and a rear wall 308. Other arrangements are of course contemplated. Various dimensions of the PSU exhaust duct 202 are also contemplated. For example, in some cases, the left wall 304 may create a depth of the PSU exhaust duct 202 of ten millimeters (10 mm), and in other cases, the left wall 303 may create a depth of the PSU exhaust duct 202 of one hundred millimeters (100 mm). Other narrower or wider depths are contemplated. In at least some cases, a mechanism that changes the depth of PSU exhaust duct 202 is also included. One or more dimensions of the PSU exhaust duct 202 cooperate to create or otherwise permit a selected airflow in the enclosed space 210 between the PSU exhaust port 116 and the interior 208 of the server 200. In some cases, the airflow is about twenty cubic feet per minute (20 CFM); in other cases, the air flow is about 150 CFM. Other airflows less than 20 CFM and greater than 150 CFM are contemplated.

The PSU exhaust duct 202 is illustrated with a PSU exhaust duct intake port 310 and a PSU exhaust duct exhaust port 312. The ports are configured to facilitate communication between the PSU exhaust port 116 and the interior 208. It should be noted that the ports are virtual in the illustrated example and may only be realized when the PSU exhaust duct 202 is attached to the server 200. For example, a portion of the PSU 102 (e.g., a rear wall) may effectively enclose a portion of the enclosed space 210 to form the PSU exhaust duct intake port 310. Another portion of the PSU 102 (e.g., the side wall 206) and a side of a server fan (e.g., server fan 110a) may enclose another portion of the enclosed space 210 to form the PSU exhaust duct exhaust port 312.

The PSU exhaust duct exhaust port 312 may be configured to be within the chassis 104. For example, as illustrated, the PSU exhaust duct exhaust port 312 may be formed at least partially by one or more extensions 314. The extensions 314 may be configured to go through at least a portion of the server rear wall 112 to extend the enclosed space 210 to the interior 208. The extensions 314 may cover unwanted gaps that may still allow reverse air flow. As an example, if portions of a top wall and/or a bottom wall of the chassis 104 proximate the gap 204 have perforations or otherwise can allow air to flow therethrough, the exhaust gas from the server fans 110 may still be forced back through the enclosed space 210 and recirculate through the PSU 102.

The extensions 314 may extend from the top wall 300, the bottom wall 302, the left wall 304, and/or the right wall 306, depending upon implementation. For example, the extensions 314 may have a width that corresponds to a width of the gap 204 and a length that corresponds to a length of the server fans 110 (e.g., a length of the gap 204). Furthermore, the extensions 314 may be portions of the walls of the PSU exhaust duct 202 that extend from or separate components attached thereto. With the extensions 314 implemented, the enclosed space 210 may have a bend or corner thereby making the PSU exhaust duct intake port 310 and the PSU exhaust duct exhaust port 312 offset from one another.

If there are no applicable gaps or perforations proximate the gap 204, then the extensions 314 may not be implemented. In such implementations, the PSU exhaust duct exhaust port 312 may be formed by the PSU exhaust duct 202 extending behind the server rear wall 112 over/behind the gap 204. Thus, when implemented without the extensions 314, the enclosed space 210 may be straight thereby making the PSU exhaust duct intake port 310 and the PSU exhaust duct exhaust port 312 co-planar.

A non-port area 316 may be closed to form the enclosed space 210 by other walls of the PSU exhaust duct 202 (not shown), by the server rear wall 112, and/or portions of the PSU 102. The non-port area 316 may have multiple portions when the extensions 314 are implemented and a single portion when the extensions 314 are not implemented.

The PSU exhaust duct 202 may have a width that corresponds to a distance between a portion of the PSU exhaust port 116 furthest from the center line of the server 200 to a far side of the gap 204. The PSU exhaust duct 202 may have a height that corresponds to a height of the server 200. The PSU exhaust duct 202 may have a depth that corresponds to a width of the gap 204 plus a length of the extensions 314. It should be noted that a depth of a main portion of the enclosed space 210 (e.g., a front to rear length of the left wall 304) may be equal to a width of the gap 204. Any larger depth may not increase air flow through the PSU exhaust duct 202 (e.g., nothing may be gained) and any less depth may decrease air flow through the PSU exhaust duct 202 (e.g., minimizing cooling of the PSU 102).

Although the PSU exhaust duct 202 is shown as a box-like structure, the PSU exhaust duct 202 may have one or more rounded portions, a hemicylindrical structure, and/or any other suitable shape(s). In more general terms, any shape/configuration may be used that forms the enclosed space 210 in communication with the PSU exhaust port 116 and the interior 208. The PSU exhaust duct 202 may be formed of any suitable materials. For example, the PSU exhaust duct 202 may be made of metal (e.g., sheet metal, steel, and/or aluminum), plastic (e.g., 3D printed or molded), wood/paper, and/or any other solid material.

### Flow Through Server with PSU Exhaust Duct

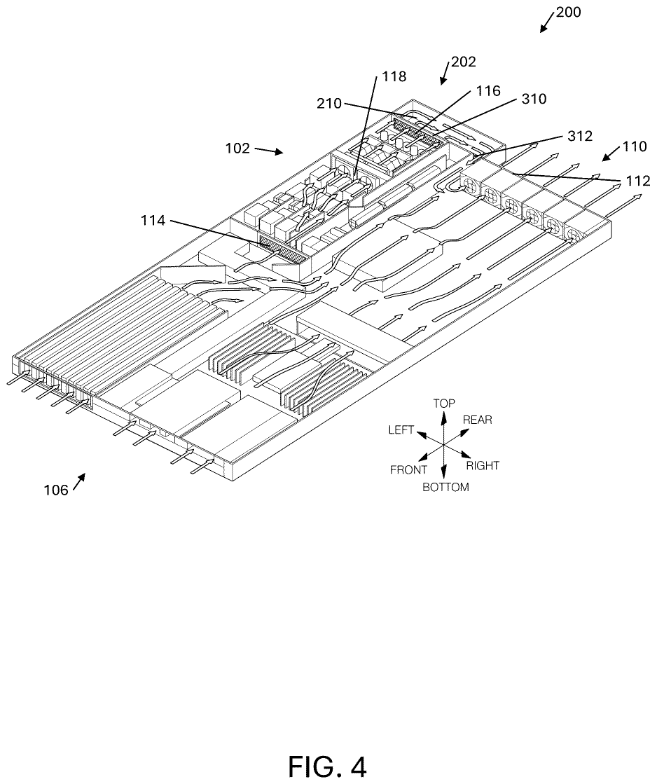

FIG. 4 illustrates an example of air flow through the server 200 with an implementation of the PSU exhaust duct 202 implemented therein. Other implementations of the PSU exhaust duct 202 as described herein are also contemplated. As can be seen, cold air is drawn through the server intake port 106 via the PSU fans 118 and the server fans 110. Once it is within the server 200, a portion of the air is drawn into the PSU 102 by the PSU fans 118 via the PSU intake port 114, and the rest of the air is drawn towards the server fans 110. The portion of the air going through the PSU 102 gets exhausted out of the PSU exhaust port 116. From there, the air exhausted from the PSU exhaust port 116 enters the PSU exhaust duct 202 via the PSU exhaust duct intake port 310, and this air travels through the enclosed space 210, and it exits the PSU exhaust duct exhaust port 312 into the interior 208 of server 200. In the illustrated example, the PSU exhaust duct 202 does not have the extensions 314. Thus, the PSU exhaust duct exhaust port 312 is formed at the server rear wall 112. If the extensions 314 were implemented, the PSU exhaust duct exhaust port 312 may be formed at a front of the server fans 110. Regardless of where the PSU exhaust duct exhaust port 312 is, the portion of air that passes through the PSU exhaust duct 202 meets the rest of the air that passes through the interior 208 of the server 200 and gets forced through the server fans 110 and outside of the server 200. Accordingly, there is no recirculation and/or flow of hot air through the PSU 102.

### Alternative Implementation

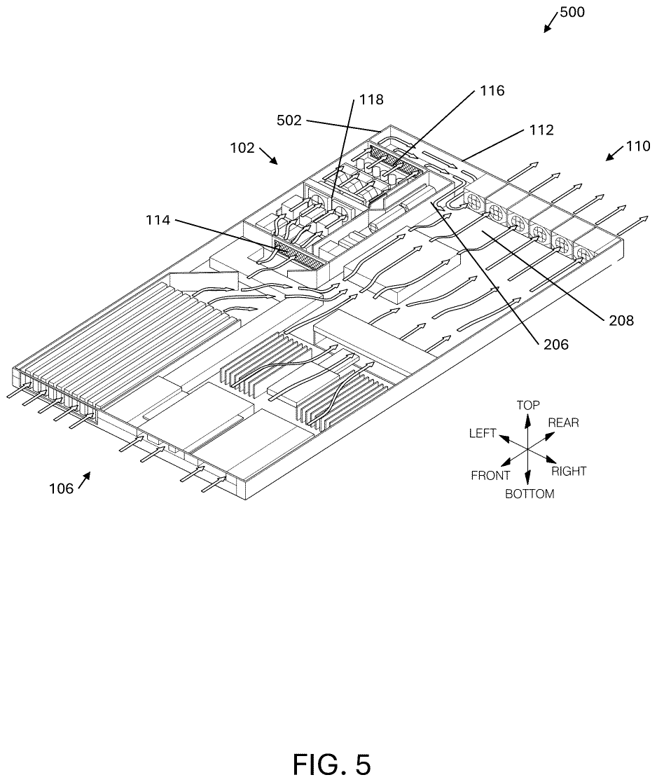

FIG. 5 illustrates an example of a server 500 with an alternative implementation of the PSU 102. Many of the components are similar to the server 100 and the server 200, thus, the same reference numbers will be used.

In the illustrated example, the PSU exhaust port 116 is not disposed at the server rear wall 112. Instead, the PSU exhaust port 116 is in communication with the interior of the server 500. In this implementation, the server rear wall 112 may be solid in a portion away from the server fans 110 and/or extend to a left server wall 502 (e.g., part of the chassis 104). Accordingly, air from the PSU exhaust port 116 may be drawn across the server rear wall 112 and/or down the side wall 206 of the PSU 102 by the positive pressure of the PSU fans 118 and/or the negative pressure within the interior 208 created by the server fans 110. The exhaust from the PSU 102 may then meet air within the interior of the server 500 to be exhausted by the server fans 110.

In order to implement this configuration within the confines of a standard-sized chassis 104, the PSU 102 may be shorter front to rear than that of the above implementations and/or be disposed closer to a front of the server 500. Furthermore, the PSU 102 may be rotated such that the PSU exhaust port 116 is within the interior 208 of the server 500 (e.g., not toward the server rear wall 112). Regardless of configuration (including the above implementations with the PSU exhaust duct 202), the PSU 102 is configured to exhaust into the interior 208, thereby preventing recirculation of hot air back through the PSU 102.

### Example Data Center

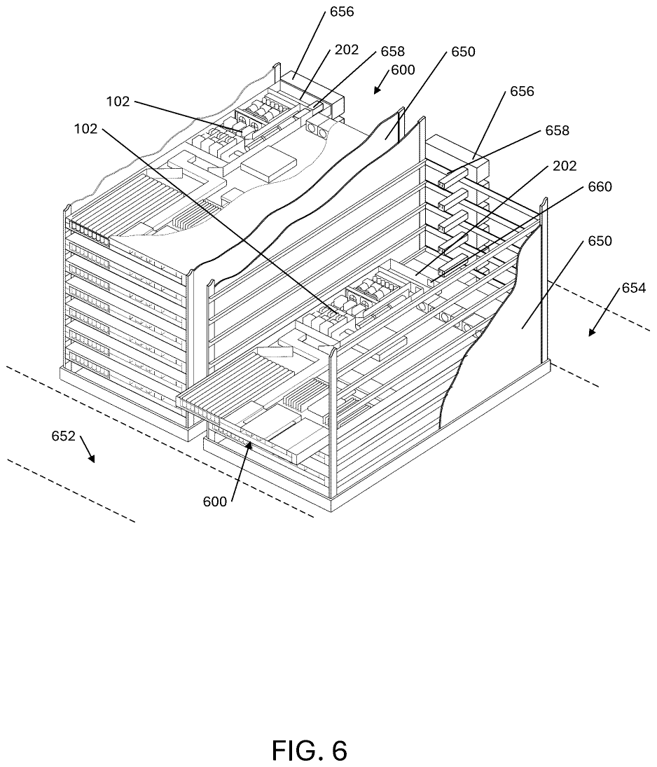

FIG. 6 illustrates a plurality of servers 600 with yet one more implementation of the PSU exhaust duct 202. Many of the components are similar to other servers of the present disclosure, thus, the same reference numbers will be used.

The servers 600 are arranged in server racks 650. Although multiple servers 600 are shown in each of the server racks 650, a server 600 may be the only server arranged in a server rack 650.

A data center may include any number of server racks 650 (e.g., two are shown adjacent to one another). In cases where a data center includes a plurality of server racks 650, any suitable number of server racks 650 may be arranged in one or more rows, and in such cases, each row may be positioned to form or otherwise participate between a cold aisle 652 and a hot aisle 654. The airflow patterns shown in the above figures illustrate cold air being drawn from the cold aisle 652 through the server intake port 106. The air from the cold aisle is heated as it passes through server 600 in one or more pathways described in the present disclosure, and the heated air passes from the interior of the server 100 through the server exhaust port 108 and into the hot aisle 654.

The server rack 650 or some other structure in the data center may optionally include one or more power distribution units (PDUs) 656. The PDUs 656 may be configured to provide power having any suitable characteristics (e.g., mains power, conditioned power, or the like) to the servers 600 in each server rack 650 (e.g., to the PSUs 102). The PDUs 656 and the PSUs 102 may be in a one to one correspondence, or a PDU 656 may supply power to multiple PSUs 102 (and, thus, servers 600). The servers 600 may be electrically coupled to the PDUs 656 via electrical conduits 658.

In some cases, the electrical conduits 658 consist of or otherwise comprise flexible cables having one or more electrically conductive means. In other cases, the electrical conduits 658 are arranged as electromechanical structures that fixedly, but releasably, couple the servers 600 to the PDUs 656 in a way that power from the PDUs 656 may be passed to the servers 600.

In some implementations, the electrical conduits 658 may pass through the PSU exhaust ducts 202 of the servers 600 (e.g., via an aperture 660), be coupled to the PSU exhaust ducts 202, or otherwise be integrally formed as part of the PSU exhaust ducts 202. In this way, the PSU exhaust ducts 202 will not undesirably impact or prevent electrically coupling data center or PDUs 656 to the PSUs 102 or servers 600.

### EXAMPLES

Example 1: A power supply unit (PSU) exhaust duct comprising: a plurality of duct walls configured to, when attached to a server, form an enclosed space in communication with: a PSU exhaust port of a PSU of the server; and an interior space of the server that is outside of the PSU.

Example 2: The PSU exhaust duct of example 1, wherein the PSU exhaust port is disposed at a server rear wall of the server.

Example 3: The PSU exhaust duct of example 2, wherein the PSU exhaust duct is configured to be mounted on the server rear wall opposite the PSU.

Example 4: The PSU exhaust duct of example 3, wherein the enclosed space extends to an end of the server rear wall.

Example 5: The PSU exhaust duct of any previous example, wherein the enclosed space is configured to cause a direction of air flow to switch between a portion of the enclosed space proximate the PSU exhaust port and a portion of the enclosed space proximate the interior space.

Example 6: The PSU exhaust duct of any previous example, wherein the enclosed space is in communication with the interior space of the server via a space between one or more server fans of the server and the PSU.

Example 7: The PSU exhaust duct of example 6, wherein at least one of a duct top wall or a duct bottom wall of the duct walls includes an extension portion configured to enclose the space between the server fans and the PSU.

Example 8: The PSU exhaust duct of any previous example, wherein the enclosed space is wider than the PSU.

Example 9: The PSU exhaust duct of any previous example, wherein the duct walls include: a top duct wall configured to be parallel with a server top wall of the server; a bottom duct wall offset from the top duct wall to form a height of the PSU exhaust duct; at least one side duct wall connecting the top duct wall and the bottom duct wall; and a duct rear wall connecting the top duct wall, the bottom duct wall, and the side duct wall.

Example 10: The PSU exhaust duct of example 9, wherein a width of the PSU exhaust duct normal to the side duct wall corresponds to a distance from an extent of the PSU exhaust duct furthest from one or more server fans of the server to a closest server fan of the server fans.

Example 11: The PSU exhaust duct of example 10, wherein a depth of the PSU exhaust duct is configured to be equal to a distance between the PSU and the closest server fan.

Example 12: The PSU exhaust duct of example 11, wherein at least one of the top duct wall or the bottom duct wall includes an extension with a width that corresponds to the distance between the PSU and the closest server fan and a length that corresponds to a depth of the server fans.

Example 13: The PSU exhaust duct of any previous example, wherein the PSU exhaust duct forms an aperture configured to receive an electrical conduit.

Example 14: A server comprising: a power supply unit (PSU) including a PSU exhaust port and one or more PSU fans configured to force air out of the PSU via the PSU exhaust port; and a PSU exhaust duct forming an enclosed space in communication with the PSU exhaust port and an interior space of the server that is outside of the PSU.

Example 15: The server of example 14, wherein the server includes a server exhaust port and one or more server fans configured to force air out of the server via the server exhaust port; and the interior space of the server corresponds to an intake side of the server fans.

Example 16: The server of example 15, wherein the server exhaust port and the PSU exhaust port are approximately co-planar.

Example 17: The server of example 16, wherein at least a majority of the PSU exhaust duct is disposed on a side of a plane of the server exhaust port opposite the PSU.

Example 18: The server of example 17, wherein the enclosed space is in communication with an area between the server fans and the PSU.

Example 19: The server of example 18, wherein the PSU exhaust duct extends between the server fans and the PSU from the plane of the server exhaust port at least a length of the server fans in a flow direction of the server fans.

Example 20: A server comprising: a server rear wall; a server exhaust port formed by the server rear wall and in communication with an exterior of the server; one or more server fans disposed proximate the server exhaust port and configured to receive air from an interior of the server and force the air out of the server via the server exhaust port; and a power supply unit (PSU) including a PSU exhaust port and one or more PSU fans configured to force air out of the PSU via the PSU exhaust port and into the interior of the server.

Example 21: The server of example 20, wherein: a portion of the server rear wall that is not the server exhaust port is configured to not allow airflow therethrough; and the PSU exhaust port is offset from the portion of the server rear wall.

Example 22: The server of example 20 or 21, further comprising at least one electrical conduit arranged between the PSU exhaust port and the server rear wall and configured to electrically couple the PSU to a power source.

Example 23: A server comprising: a server rear wall; a server exhaust port formed by the server rear wall and in communication with an exterior of the server; one or more server fans disposed proximate the server exhaust port and configured to receive air from an interior of the server and force the air out of the server via the server exhaust port; and a power supply unit (PSU) including a PSU exhaust port and one or more PSU fans configured to force air out of the PSU via the PSU exhaust port; and a PSU exhaust duct having at least one electrical conduit, the PSU exhaust duct arranged in communication with the PSU exhaust port to direct at least some of the air passed via the PSU exhaust port into the interior of the server, wherein the at least one electrical conduit is arranged to electrically couple the PSU to a power source.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

The server may also include a power supply configured to supply power to various components within the server. The power supply may be configured to adapt or change incoming power (e.g., alternating current to direct current and/or stepping up or stepping down voltage). Furthermore, the power supply may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionality of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply, rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### Conclusion

The terminology used herein is for the purpose of describing particular implementations only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various implementations were chosen and described in order to best explain the principles of this disclosure and the practical application, and to enable others of ordinary skill in the art to understand this disclosure for various implementations with various modifications as are suited to the particular use contemplated.

What is claimed is:

1. A power supply unit (PSU) exhaust duct comprising:
a plurality of duct walls configured to, when attached to a server, form an enclosed space in communication with:
a PSU exhaust port of a PSU of the server; and
an interior space of the server that is outside of the PSU.

2. The PSU exhaust duct of claim 1, wherein the PSU exhaust port is disposed at a server rear wall of the server.

3. The PSU exhaust duct of claim 2, wherein the PSU exhaust duct is configured to be mounted on the server rear wall opposite the PSU.

4. The PSU exhaust duct of claim 3, wherein the enclosed space extends to an end of the server rear wall.

5. The PSU exhaust duct of claim 1, wherein the enclosed space is configured to cause a direction of air flow to switch between a portion of the enclosed space proximate the PSU exhaust port and a portion of the enclosed space proximate the interior space.

6. The PSU exhaust duct of claim 1, wherein the enclosed space is in communication with the interior space of the server via a space between one or more server fans of the server and the PSU.

7. The PSU exhaust duct of claim 6, wherein at least one of a duct top wall or a duct bottom wall of the duct walls includes an extension portion configured to enclose the space between the server fans and the PSU.

8. The PSU exhaust duct of claim 1, wherein the enclosed space is wider than the PSU.

9. The PSU exhaust duct of claim 1, wherein the duct walls include:
a top duct wall configured to be parallel with a server top wall of the server;
a bottom duct wall offset from the top duct wall to form a height of the PSU exhaust duct;
at least one side duct wall connecting the top duct wall and the bottom duct wall; and
a duct rear wall connecting the top duct wall, the bottom duct wall, and the side duct wall.

10. The PSU exhaust duct of claim 9, wherein a width of the PSU exhaust duct normal to the side duct wall corresponds to a distance from an extent of the PSU exhaust duct furthest from one or more server fans of the server to a closest server fan of the server fans.

11. The PSU exhaust duct of claim 10, wherein a depth of the PSU exhaust duct is configured to be equal to a distance between the PSU and the closest server fan.

12. The PSU exhaust duct of claim 11, wherein at least one of the top duct wall or the bottom duct wall includes an extension with a width that corresponds to the distance between the PSU and the closest server fan and a length that corresponds to a depth of the server fans.

13. A server comprising:
a power supply unit (PSU) including a PSU exhaust port and one or more PSU fans configured to force air out of the PSU via the PSU exhaust port; and
a PSU exhaust duct forming an enclosed space in communication with the PSU exhaust port and an interior space of the server that is outside of the PSU.

14. The server of claim 13, wherein the server includes a server exhaust port and one or more server fans configured to force air out of the server via the server exhaust port; and
the interior space of the server corresponds to an intake side of the server fans.

15. The server of claim 14, wherein the server exhaust port and the PSU exhaust port are approximately co-planar.

16. The server of claim 15, wherein at least a majority of the PSU exhaust duct is disposed on a side of a plane of the server exhaust port opposite the PSU.

17. The server of claim 16, wherein the enclosed space is in communication with an area between the server fans and the PSU.

18. The server of claim 17, wherein the PSU exhaust duct extends between the server fans and the PSU from the plane of the server exhaust port at least a length of the server fans in a flow direction of the server fans.

19. A server comprising:
a server rear wall;
a server exhaust port formed by the server rear wall and in communication with an exterior of the server;
one or more server fans disposed proximate the server exhaust port and configured to receive air from an interior of the server and force the air out of the server via the server exhaust port;
a power supply unit (PSU) including a PSU exhaust port and one or more PSU fans configured to force air out of the PSU via the PSU exhaust port and into an interior of the server; and
at least one electrical conduit arranged between the PSU exhaust port and the server rear wall and configured to electrically couple the PSU to a power source.

20. The server of claim 19, wherein:
a portion of the server rear wall that is not the server exhaust port is configured to not allow airflow therethrough; and
the PSU exhaust port is offset from the portion of the server rear wall.
